(19) United States
(12) Patent Application Publication
(10) Pub. No.: US 2017/0325330 A1
(43) Pub. Date: Nov. 9, 2017

(54) MANUFACTURING METHOD OF CIRCUIT SUBSTRATE

(71) Applicant: Subtron Technology Co., Ltd., Hsinchu County (TW)

(72) Inventors: Chin-Sheng Wang, Hsinchu County (TW); Ching-Sheng Chen, Hsinchu County (TW); Ching-Ta Chen, Hsinchu County (TW); Mei-Chin Chang, Hsinchu County (TW)

(21) Appl. No.: 15/176,130

(22) Filed: Jun. 7, 2016

(30) Foreign Application Priority Data
May 6, 2016 (TW) 105114094

(51) Int. Cl. H05K 1/02; H05K 1/11; H05K 3/42; H05K 3/46

(52) U.S. Cl. CPC H05K 1/0242; H05K 3/4661; H05K 1/115; H05K 3/429

(57) ABSTRACT

A manufacturing method of a circuit substrate includes the following steps. A core layer having a core dielectric layer, a first patterned circuit layer and a second patterned circuit layer is provided. An electroless plating nickel layer is formed on the first patterned circuit layer and the second patterned circuit layer. The electroless plating nickel layer has a first thickness, and the first thickness is between 1 micrometer and 10 micrometers. A reducing process is performed on the electroless plating nickel layer so that the electroless plating nickel layer is thinned from the first thickness to a second thickness to form a thinned electroless plating nickel layer. The second thickness is between 0.01 micrometers and 0.9 micrometers. An electroless plating palladium layer is formed on the thinned electroless plating nickel layer. A surface metal passivation layer is formed on the electroless plating palladium layer.

### CROSS-REFERENCE TO RELATED APPLICATION

This application claims the priority benefit of Taiwan application serial no. 105114094, filed on May 6, 2016. The entirety of the above-mentioned patent application is hereby incorporated by reference herein and made a part of this specification.

### BACKGROUND OF THE INVENTION

### Field of the Invention

The invention relates to a circuit substrate, and particularly relates to a manufacturing method of a circuit substrate.

### Description of Related Art

In a current manufacturing method of a circuit substrate, after pads are formed, an electroless plating nickel layer, an electroless plating palladium layer and an electroless plating gold layer are often sequentially formed on the pads to define a surface-coating layer with electroless plating nickel-palladium-gold, so as to effectively protect the pads. In order for the circuit substrate to be used in a high frequency microwave communication, a thickness of the electroless plating nickel layer must be less than 1 micrometer to reduce the interference to high frequency microwave signal. However, in terms of the electroless plating nickel layer having a thinner thickness compared with the electroless plating nickel layer having a general thickness (the thickness is more than 1 micrometer), the electroless plating nickel layer is directly plated and formed on the pads currently, and the thickness thereof is hard to be less than 1 micrometer. The process control is difficult, and the problems, such as poor quality, uneven thickness and poor coverage, are easily generated. Additionally, since the thickness of the electroless plating nickel layer is thin and the coverage of the electroless plating nickel layer is poor, and thus the coverage of the electroless plating palladium layer subsequently formed on the electroless plating nickel layer is poor. Thus, it is difficult to maintain the integrity of the signal when used in the high frequency microwave communication.

### SUMMARY OF THE INVENTION

The invention provides a manufacturing method of a circuit substrate, which can form a thinned electroless plating nickel layer. The thickness and quality of the thinned electroless plating nickel layer is easily and effectively controlled to meet the needs of the high frequency microwave communication.

The manufacturing method of the circuit substrate of the invention including the following manufacturing steps. A core layer is provided. The core layer includes a core dielectric layer, a first patterned circuit layer and a second patterned circuit layer. The core dielectric layer has an upper surface and a lower surface opposite to each other.

The first patterned circuit layer is disposed on the upper surface of the core dielectric layer, and the second patterned circuit layer is disposed on the lower surface of the core dielectric layer. An electroless plating nickel layer is formed on the first patterned circuit layer and the second patterned circuit layer and covers the first patterned circuit layer and the second patterned circuit layer. The electroless plating nickel layer has a first thickness, and the first thickness is between 1 micrometer and 10 micrometers. A reducing process is performed on the electroless plating nickel layer so that the electroless plating nickel layer is thinned from the first thickness to a second thickness to form a thinned electroless plating nickel layer. The second thickness is between 0.01 micrometers and 0.9 micrometers. An electroless plating palladium layer is formed on the thinned electroless plating nickel layer and covers the thinned electroless plating nickel layer. A surface metal passivation layer is formed on the electroless plating palladium layer and covers the electroless plating palladium layer.

According to an embodiment of the invention, the first thickness is between 2 micrometers and 6 micrometers.

According to an embodiment of the invention, the second thickness is between 0.08 micrometers and 0.2 micrometers.

According to an embodiment of the invention, the surface metal passivation layer includes an electroless plating gold layer or an electroless plating silver layer.

According to an embodiment of the invention, the manufacturing method of the circuit substrate further includes, after providing the core layer and before forming the electroless plating nickel layer, or after forming the surface metal passivation layer, forming a solder mask layer on the upper surface and the lower surface of the core dielectric layer.

According to an embodiment of the invention, the manufacturing method of the circuit substrate further includes forming a third patterned circuit layer on the upper surface of the core dielectric layer; and forming an organic solderability preservative layer (OSP layer) on the third patterned circuit layer and covering the third patterned circuit layer.

According to an embodiment of the invention, the electroless plating nickel layer is a phosphorus-containing electroless plating nickel layer.

According to an embodiment of the invention, the reducing process is an etching process.

According to an embodiment of the invention, a thickness of the electroless plating palladium layer is between 0.03 micrometers and 0.2 micrometers.

According to an embodiment of the invention, a thickness of the surface metal passivation layer is between 0.03 micrometers and 0.2 micrometers.

According to an embodiment of the invention, the core layer further includes at least one conductive via penetrating the core dielectric layer and electrically connected with the first patterned circuit layer to the second patterned circuit layer.

In an embodiment of the invention, a circuit substrate that includes a core layer, a thinned electroless plating nickel layer, an electroless plating palladium layer and a surface metal passivation layer. The core layer includes a core dielectric layer, a first patterned circuit layer and a second patterned circuit layer, wherein the core dielectric layer has an upper surface and a lower surface opposite to each other, the first patterned circuit layer is disposed on the upper surface of the core dielectric layer, and the second patterned circuit layer is disposed on the lower surface of the core dielectric layer. The thinned electroless plating nickel layer is disposed on the first patterned circuit layer and the second patterned circuit layer, and covering the first patterned circuit layer and the second patterned circuit layer, wherein the electroless plating nickel layer has a thickness, and the thickness is between 0.01 micrometers and 0.9 micrometers. The electroless plating palladium layer is disposed on the thinned electroless plating nickel layer and covering the thinned electroless plating nickel layer. The surface metal passivation layer is disposed on the electroless plating palladium layer and covering the electroless plating palladium layer.

According to an embodiment of the invention, the circuit substrate further includes a third patterned circuit layer and an organic solderability preservative layer. The third patterned circuit layer is disposed on the upper surface of the core dielectric layer. The organic solderability preservative layer is disposed on the third patterned circuit layer and covering the third patterned circuit layer.

Based on the above, the manufacturing method of the circuit substrate of the invention is to form the electroless plating nickel layer having the first thickness of more than 1 micrometer on the first patterned circuit layer and the second patterned circuit layer of the core layer first, such that the coverage of the electroless plating nickel layer on the first patterned circuit layer and the second patterned circuit layer is better and more complete. After that, the reducing process is performed on the electroless plating nickel layer having the first thickness to form the thinned electroless plating nickel layer having the second thickness of less than 1 micrometer. In comparison with the conventional electroless plating nickel layer directly formed on the copper pads, the thinned electroless plating nickel layer formed by the manufacturing method of the circuit substrate of the invention may have a better coverage and the thickness control thereof is relatively simple compared with the first patterned circuit layer and the second patterned circuit layer, or the electroless plating palladium layer subsequently formed thereon. Therefore, the signal of the circuit substrate formed by the manufacturing method of the circuit substrate of the invention can be maintained complete when used in the high frequency microwave communication, and the circuit substrate can provide high-quality signal transmission results.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1F are schematic cross-sectional views of a manufacturing method of a circuit substrate according to an embodiment of the invention.

FIG. 2 is a schematic cross-sectional view of a circuit substrate according to another embodiment of the invention.

FIG. 3 is a schematic cross-sectional view of a circuit substrate according to another embodiment of the invention.

FIG. 4 is a schematic cross-sectional view of a circuit substrate according to another embodiment of the invention.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

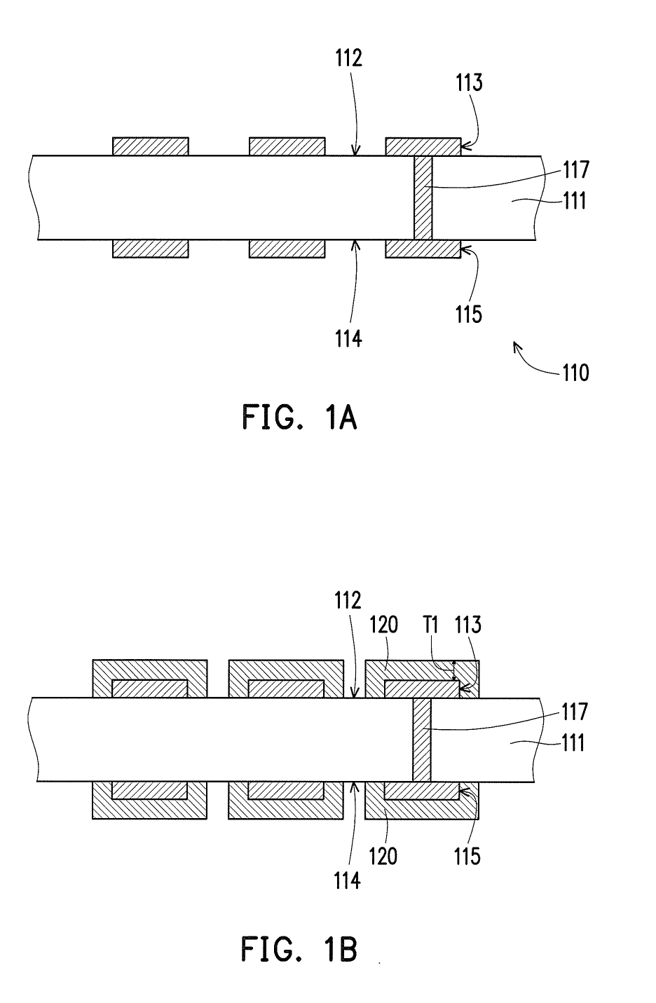

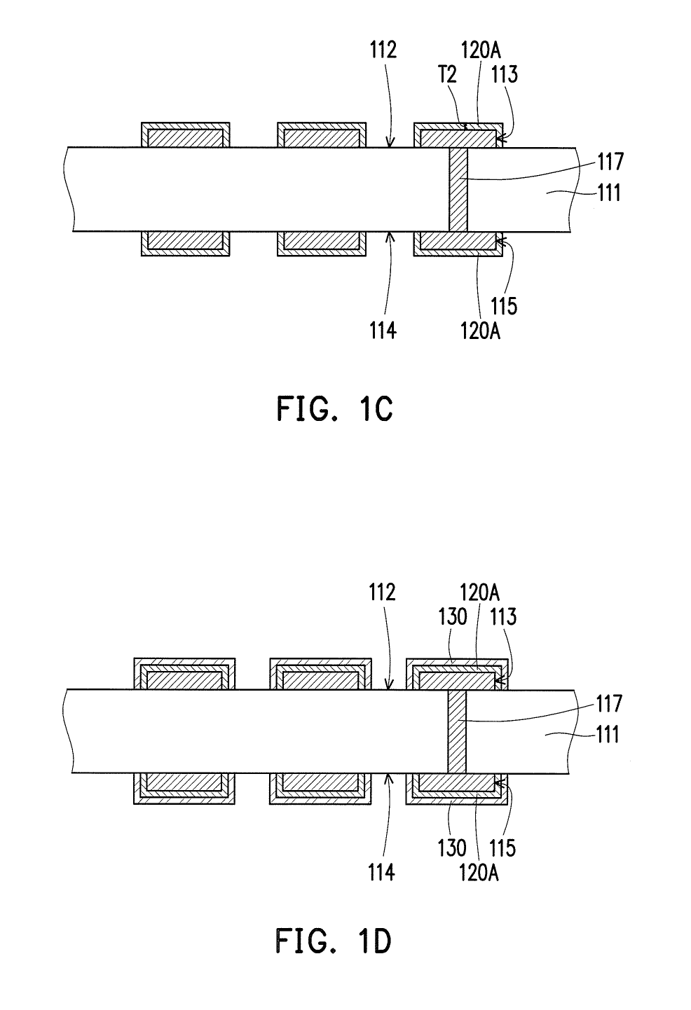

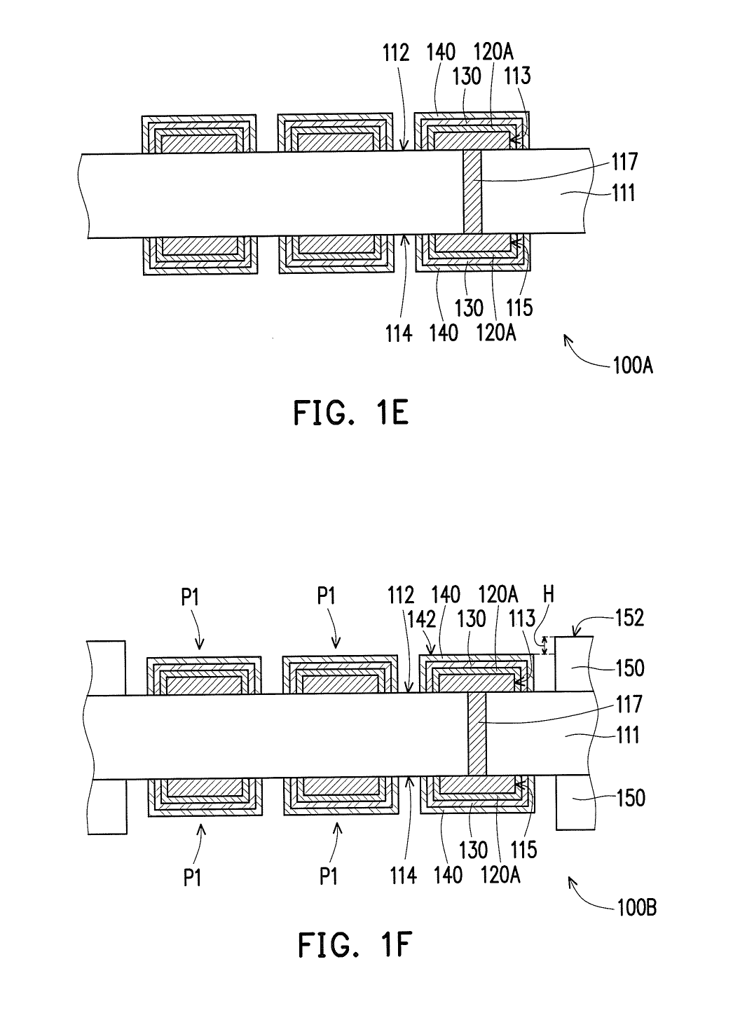

FIG. 1A to FIG. 1F are schematic cross-sectional views of a manufacturing method of a circuit substrate according to an embodiment of the invention. With regard to the manufacturing method of the circuit substrate of the embodiment, referring to FIG. 1A first, a core layer 110 is provided. Specifically, the core layer 110 includes a core dielectric layer 111, a first patterned circuit layer 113 and a second patterned circuit layer 115. The core dielectric layer 111 has an upper surface 112 and a lower surface 114 opposite to each other. The first patterned circuit layer 113 is disposed on the upper surface 112 of the core dielectric layer 111, and the second patterned circuit layer 115 is disposed on the lower surface 114 of the core dielectric layer 111. Additionally, the core layer 110 of the embodiment may further selectively include at least one conductive via 117 penetrating the core dielectric layer 111 and connected with the first patterned circuit layer 113 and the second patterned circuit layer 115. Here, the first patterned circuit layer 113 and the second patterned circuit layer 115 may have a pad respectively, for example, and a material of the first patterned circuit layer 113 and the second patterned circuit layer 115 is copper, for example. However, the invention is not limited thereto.

Next, referring to FIG. 1B, an electroless plating nickel layer 120 is formed on the first patterned circuit layer 113 and the second patterned circuit layer 115 and covers the first patterned circuit layer 113 and the second patterned circuit layer 115. Here, as shown in FIG. 1B, the first patterned circuit layer 113 and the second patterned circuit layer 115 are completely covered by the electroless plating nickel layer 120, and a portion of the upper surface 112 and a portion of the lower surface 114 of the core dielectric layer 111 are exposed, wherein the electroless plating nickel layer 120 can be a phosphorus-containing electroless plating nickel layer, for example. Particularly, the electroless plating nickel layer 120 has a first thickness T1, and the first thickness T1 can be between 1 micrometer and 10 micrometers. Preferably, the first thickness T1 is between 2 micrometers and 6 micrometers. That is to say, the electroless plating nickel layer 120 of the embodiment has the first thickness T1 of more than 1 micrometer. Namely, the electroless plating nickel layer 120 has a sufficient thickness to achieve the result of complete covering. Thus, the electroless plating nickel layer 120 may have a better and more complete coverage relative to the first patterned circuit layer 113 and the second patterned circuit layer 115.

Then, referring to FIG. 1C, a reducing process, i.e. a thickness reducing process or a thinning process, is performed on the electroless plating nickel layer 120, so that the electroless plating nickel layer 120 is thinned from the first thickness T1 to a second thickness T2 to form a thinned electroless plating nickel layer 120A, wherein the second thickness T2 is between 0.01 micrometers and 0.9 micrometers. Preferably, the second thickness T2 is between 0.08 micrometers and 0.2 micrometers. Here, the reducing process is an etching process, for example. That is, the electroless plating nickel layer 120 is thinned by means of etching, such as nickel etching liquid, to form the thinned electroless plating nickel layer 120A. As a result, the thickness of the thinned electroless plating nickel layer 120A is quite simple in control. Also, the thinned electroless plating nickel layer 120A may have a better process yield and a better quality of the process. Therefore, in comparison with the conventional electroless plating nickel layer directly formed on the pad, the thinned electroless plating nickel layer 120A of the embodiment can achieve extremely thin thickness and still has a better uniformity and coverage.

Thereafter, referring to FIG. 1D, an electroless plating palladium layer 130 is formed on the thinned electroless plating nickel layer 120A and covers the thinned electroless plating nickel layer 120A. Here, the thinned electroless plating nickel layer 120A is completely covered by the electroless plating palladium layer 130, and a portion of the upper surface 112 and a portion of the lower surface 114 of the core dielectric layer 111 are exposed, wherein a thickness of the electroless plating palladium layer 130 can be between 0.03 micrometers and 0.2 micrometers, for example. Since the embodiment is to form the electroless plating nickel layer 120 having the first thickness T1 of more than 1 micrometer on the first patterned circuit layer 113 and the second patterned circuit layer 115 first, and then the reducing process is performed on the electroless plating nickel layer 120 having the first thickness T1 to form the thinned electroless plating nickel layer 120A having the second thickness T2 of less than 1 micrometer, the covering of the thinned electroless plating nickel layer 120A is complete Thus, the electroless plating palladium layer 130 can also have a better and more complete coverage.

At last, referring to FIG. 1E, a surface metal passivation layer 140 is formed on the electroless plating palladium layer 130 and covers the electroless plating palladium layer 130. Here, the electroless plating palladium layer 130 is completely covered by the surface metal passivation layer 140, and a portion of the upper surface 112 and a portion of the lower surface 114 of the core dielectric layer 111 are exposed, wherein the surface metal passivation layer 140 is an electroless plating gold layer or an electroless plating silver layer, for example. For instance, the electroless plating gold layer or the electroless plating silver layer may be an immersion gold layer or an immersion silver layer respectively, and a thickness of the surface metal passivation layer 140 is between 0.03 micrometers and 0.2 micrometers, for example. At this point, the production of a circuit substrate 110A has been completed.

In order to effectively protect the first patterned circuit layer 113 and the second patterned circuit layer 115, in the manufacturing method of the circuit substrate of the embodiment, a solder mask layer 150 may be selectively formed on the upper surface 112 and the lower surface 114 of the core dielectric layer 111 after forming the surface metal passivation layer 140, so as to form a circuit substrate 100B having the solder mask layer 150. As shown in FIG. 1F, a top surface 152 of the solder mask layer 150 and a top surface 142 of the surface metal passivation layer 140 of the circuit substrate 100B has a height difference H therebetween, and an orthogonal projection of the solder mask layer 150 on the core dielectric layer 111 may not overlap an orthogonal projection of the first patterned circuit layer 113 and the second patterned circuit layer 115 on the core dielectric layer 111. Thus, a plurality of non-solder mask defined (NSMD) pads P1 can be defined.

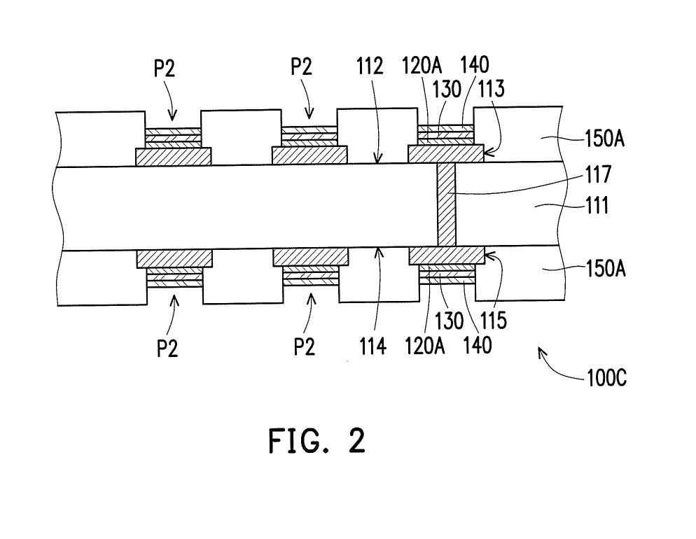

Naturally, the invention does not limit the configuration relationship between the solder mask layer 150, and the first patterned circuit layer 113 and the second patterned circuit layer 115. In other embodiments, referring to FIG. 2, a solder mask layer 150A may also be formed on the upper surface 112 and lower surface 114 of the core dielectric layer 111 after providing the core layer 110 and before forming the electroless plating nickel layer 120, so as to form a circuit substrate 100C having the solder mask layer 150A. As shown in FIG. 2, the solder mask layer 150A covers a portion of the first patterned circuit layer 113 and a portion of the second patterned circuit layer 115, and then the thinned electroless plating nickel layer 120A, the electroless plating palladium layer 130 and the surface metal passivation layer 140 are sequentially formed on the first patterned circuit layer 113 and the second patterned circuit layer 115 exposed by the solder mask layer 150A, and cover on the first patterned circuit layer 113 and the second patterned circuit layer 115 exposed by the solder mask layer 150A. Thus, a plurality of solder mask defined (SMD) pads P2 can be defined.

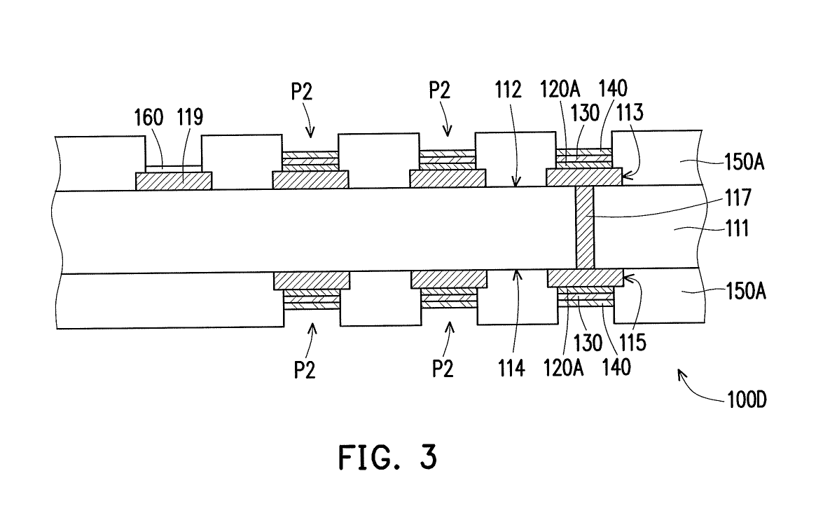

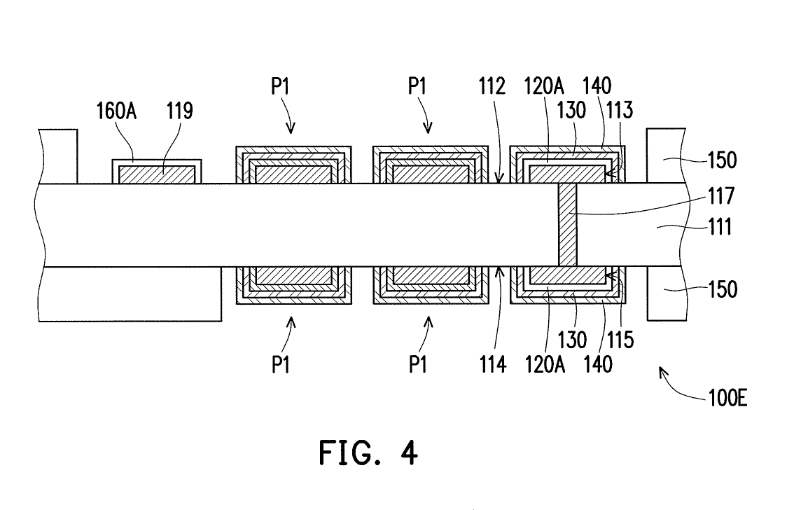

FIG. 3 is a schematic cross-sectional view of a circuit substrate according to another embodiment of the invention. The component notations and partial details of the structures hereinafter provided in the embodiments can be the same as or similar to the previous embodiment, wherein the same notations represent the same or similar components while the repeated same details are omitted in the embodiment, which can refer to the previous embodiment. Referring to FIG. 3, a circuit substrate 100D of the embodiment is similar to the circuit substrate 100C of FIG. 2, and the difference therebetween is that, the manufacturing method of the circuit substrate 100D of the embodiment further includes forming a third patterned circuit layer 119 on the upper surface 112 of the core dielectric layer 111, and forming an organic solderability preservative (OSP) layer 160 on the third patterned circuit layer 119 and covering the third patterned circuit layer 119. Here, the third patterned circuit layer 119 may be formed with the first patterned circuit layer 113 at the same time, for example, and the third patterned circuit layer 119 may be protected temporarily. After the electroless plating nickel layer 120 and the surface metal passivation layer 140 are formed, the protection of the third patterned circuit layer 119 is removed. Then, the organic solderability preservative layer 160 is Ruined on the third patterned circuit layer 119, and is not limited thereto. Additionally, as shown in FIG. 3, it shows that the first patterned circuit layer 113 is electrically connected with the second patterned circuit layer 115 by the conductive via 117. However, in other embodiments not shown, it may be that the third patterned circuit layer 119 is electrically connected with the second patterned circuit layer 115 by the conductive via 117 selectively, which is still within the scope of the invention.

FIG. 4 is a schematic cross-sectional view of a circuit substrate according to another embodiment of the invention. The component notations and partial details of the structures hereinafter provided in the embodiments can be the same as or similar to the previous embodiment, wherein the same notations represent the same or similar components while the repeated same details are omitted in the embodiment, which can refer to the previous embodiment. Referring to FIG. 4, a circuit substrate 100E of the embodiment is similar to the circuit substrate 100B of FIG. 1F, and the difference therebetween is that, the manufacturing method of the circuit substrate 100E of the embodiment further includes forming the third patterned circuit layer 119 on the upper surface 112 of the core dielectric layer 111, and forming an organic solderability preservative layer 160A on the third patterned circuit layer 119 and covering the third patterned circuit layer 119. Here, the third patterned circuit layer 119 may be formed with the first patterned circuit layer 113 at the same time. The organic solderability preservative layer 160A may be formed after forming the electroless plating nickel layer 120 and the surface metal passivation layer 140, and is not limited thereto. Additionally, as shown in FIG. 4, it shows that the first patterned circuit layer 113 is electrically connected with the second patterned circuit layer 115 by the conductive via 117. However, in other embodiments not shown, it may be that the third patterned circuit layer 119 is electrically connected with the second patterned circuit layer 115 by the conductive via 117 selectively, which is still within the scope of the invention.

In summary, the manufacturing method of the circuit substrate of the invention is to form the electroless plating nickel layer having the first thickness of more than 1 micrometer on the first patterned circuit layer and the second patterned circuit layer of the core layer first, such that the coverage of the electroless plating nickel layer on the first patterned circuit layer and the second patterned circuit layer is better. After that, the reducing process is performed on the electroless plating nickel layer having the first thickness to form the thinned electroless plating nickel layer having the second thickness of less than 0.9 micrometers. In comparison with the conventional electroless plating nickel layer directly plated on the copper pads, the thinned electroless plating nickel layer formed by the manufacturing method of the circuit substrate of the invention can form the thinned electroless plating nickel layer having an extremely thin thickness, and has a better uniformity and coverage. Since the thickness of the thinned electroless plating nickel layer is thin, it can reduce the interference to the high frequency microwave signal. Additionally, the thinned electroless plating nickel layer may have a better uniformity and coverage, and the thickness control thereof is relatively simple, compared with the first patterned circuit layer and the second patterned circuit layer, or the electroless plating palladium layer subsequently formed thereon. Therefore, the signal of the circuit substrate formed by the manufacturing method of the circuit substrate of the invention can be maintained complete when used in the high frequency microwave communication, and the circuit substrate can provide high-quality signal transmission results.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

1. A manufacturing method of a circuit substrate, comprising:
providing a core layer, the core layer comprising a core dielectric layer, a first patterned circuit layer and a second patterned circuit layer, wherein the core dielectric layer has an upper surface and a lower surface opposite to each other, the first patterned circuit layer is disposed on the upper surface of the core dielectric layer, and the second patterned circuit layer is disposed on the lower surface of the core dielectric layer;
forming an electroless plating nickel layer on the first patterned circuit layer and the second patterned circuit layer and covering the first patterned circuit layer and the second patterned circuit layer, wherein the electroless plating nickel layer has a first thickness, and the first thickness of the electroless plating nickel layer is between 1 micrometer and 10 micrometers;
performing an etching process on the electroless plating nickel layer, so that the electroless plating nickel layer is thinned from the first thickness to a second thickness to form a thinned electroless plating nickel layer, wherein the second thickness of the thinned electroless plating nickel layer is between 0.01 micrometers and 0.9 micrometers;
forming an electroless plating palladium layer on the thinned electroless plating nickel layer and covering the thinned electroless plating nickel layer; and
forming a surface metal passivation layer on the electroless plating palladium layer and covering the electroless plating palladium layer.

2. The manufacturing method of the circuit substrate according to claim 1, wherein the first thickness of the electroless plating nickel layer is between 2 micrometers and 6 micrometers.

3. The manufacturing method of the circuit substrate according to claim 1, wherein the second thickness of the thinned electroless plating nickel layer is between 0.08 micrometers and 0.2 micrometers.

4. The manufacturing method of the circuit substrate according to claim 1, wherein the surface metal passivation layer comprises an electroless plating gold layer or an electroless plating silver layer.

5. The manufacturing method of the circuit substrate according to claim 1, further comprising:
after providing the core layer and before forming the electroless plating nickel layer, or after forming the surface metal passivation layer, forming a solder mask layer on the upper surface and the lower surface of the core dielectric layer.

6. The manufacturing method of the circuit substrate according to claim 1, further comprising:
forming a third patterned circuit layer on the upper surface of the core dielectric layer; and
forming an organic solderability preservative layer on the third patterned circuit layer and covering the third patterned circuit layer.

7. The manufacturing method of the circuit substrate according to claim 1, wherein the electroless plating nickel layer is a phosphorus-containing electroless plating nickel layer.

8. (canceled)

9. The manufacturing method of the circuit substrate according to claim 1, wherein a thickness of the electroless plating palladium layer is between 0.03 micrometers and 0.2 micrometers.

10. The manufacturing method of the circuit substrate according to claim 1, wherein a thickness of the surface metal passivation layer is between 0.03 micrometers and 0.2 micrometers.

11. The manufacturing method of the circuit substrate according to claim 1, wherein the core layer further comprises at least one conductive via penetrating the core dielectric layer and electrically connected with the first patterned circuit layer to the second patterned circuit layer.

12. A circuit substrate, comprising:
a core layer, comprising a core dielectric layer, a first patterned circuit layer and a second patterned circuit layer, wherein the core dielectric layer has an upper surface and a lower surface opposite to each other, the first patterned circuit layer is disposed on the upper surface of the core dielectric layer, and the second patterned circuit layer is disposed on the lower surface of the core dielectric layer;
a thinned electroless plating nickel layer, disposed on the first patterned circuit layer and the second patterned circuit layer, and covering the first patterned circuit layer and the second patterned circuit layer, wherein the thinned electroless plating nickel layer has a thickness, and the thickness is between 0.01 micrometers and 0.9 micrometers;
an electroless plating palladium layer, disposed on the thinned electroless plating nickel layer and covering the thinned electroless plating nickel layer; and
a surface metal passivation layer, disposed on the electroless plating palladium layer and covering the electroless plating palladium layer.

13. The circuit substrate according to claim 12, further comprising:
a third patterned circuit layer, disposed on the upper surface of the core dielectric layer; and
an organic solderability preservative layer, disposed on the third patterned circuit layer and covering the third patterned circuit layer.
